(19) United States
(12) Patent Application Publication
(10) Pub. No.: US 2008/0102618 A1
(43) Pub. Date: May 1, 2008

(54) METHOD OF MANUFACTURING SEMICONDUCTOR DEVICE

(75) Inventor: Jae Heon Kim, Cheorwon-gun (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/752,878

(22) Filed: May 23, 2007

(30) Foreign Application Priority Data
Oct. 31, 2006 (KR) 2006-106601

(51) Int. Cl. H01L 21/3205

(52) U.S. Cl. 438/594; 257/E21.294

(57) ABSTRACT

A method of manufacturing a semiconductor device is provided. A first spacer is formed over a semiconductor substrate including an isolation layer that defines an active region. A part of the first spacer is removed to expose part of the active region. The exposed active region is etched to form a first recess. The first spacer is removed. A tunnel oxide layer and a conductive layer are formed over the surface including the recess. A second spacer is formed over the surface including the conductive layer. A part of the second spacer is removed to expose part of the conductive layer. The exposed conductive layer is etched to form a second recess. The second spacer is removed. A dielectric layer and a control gate are then formed over the conductive layer.

### CROSS-REFERENCES TO RELATED APPLICATIONS

The present application claims priority to Korean patent application number 2006-106601, filed on Oct. 31, 2006, which is incorporated by reference in its entirety.

### BACKGROUND OF THE INVENTION

The present invention relates, in general, to semiconductor devices and, more particularly, to a method of manufacturing a semiconductor device, in which the reliability of the device can be improved and an interference phenomenon can be reduced by increasing the coupling ratio.

In semiconductor devices, in particular, a flash memory device, the height and area of a floating gate gradually decrease as the device becomes highly integrated with the development of technology. As the coupling ratio decreases, program efficiency of a flash memory cell is lowered. Further, an interference phenomenon occurring between neighboring cells is increased. Accordingly, program voltage distributions between word lines are increased.

### SUMMARY OF THE INVENTION

Accordingly, the present invention addresses the above problems, and discloses a method of manufacturing a semiconductor device which increases the width of an active region without a mask process, uniformly increases the area of a floating gate, and decreases an interference phenomenon between neighboring floating gates by forming a recess using a spacer.

According to an aspect of the present invention, a method of manufacturing a semiconductor device is provided. A first spacer is formed over a semiconductor substrate including an isolation layer that defines an active region. A part of the first spacer is removed to expose part of the active region. The exposed active region is etched to form a first recess. The first spacer is removed. A tunnel oxide layer and a conductive layer are formed over the surface including the recess. A second spacer is formed over the surface including the conductive layer. A part of the second spacer is removed to expose part of the conductive layer. The exposed conductive layer is etched to form a second recess. The second spacer is removed. A dielectric layer and a control gate are formed over the conductive layer.

According to another aspect of the present invention, a method of manufacturing a semiconductor device is provided. A first spacer is formed over a semiconductor substrate including an isolation layer that defines an active region. A part of the first spacer is removed to expose part of the active region. The exposed active region is etched to form a first recess. A tunnel oxide layer and a conductive layer are formed over the surface including the recess. A second spacer is formed over the surface including the conductive layer. A part of the second spacer is removed to expose part of the conductive layer. The exposed conductive layer is etched to form a second recess. A third spacer is formed over the conductive layer. A part of the third spacer is removed to expose part of the isolation layer. The exposed isolation layer is etched to form a third recess. A dielectric layer and a control gate are formed over the conductive layer.

### BRIEF DESCRIPTION OF THE DRAWINGS

FIGS. 1A to 1K are cross-sectional views illustrating a method of manufacturing a semiconductor device according to an embodiment of the present invention; and

FIGS. 2A to 2D are cross-sectional views illustrating a method of manufacturing a semiconductor device according to another embodiment of the present invention.

### DESCRIPTION OF SPECIFIC EMBODIMENTS

Specific embodiments according to the present patent will be described with reference to the accompanying drawings.

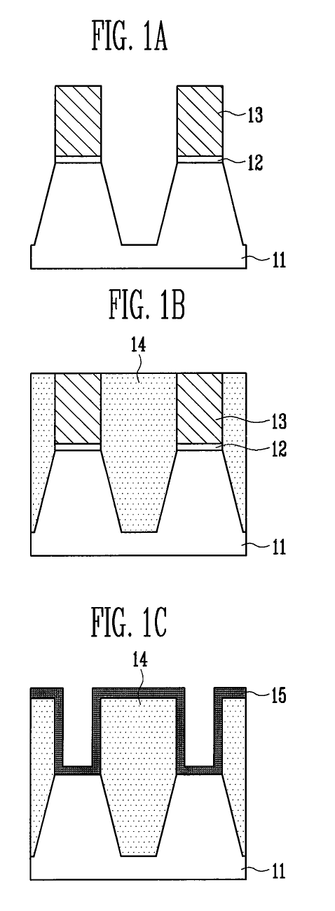

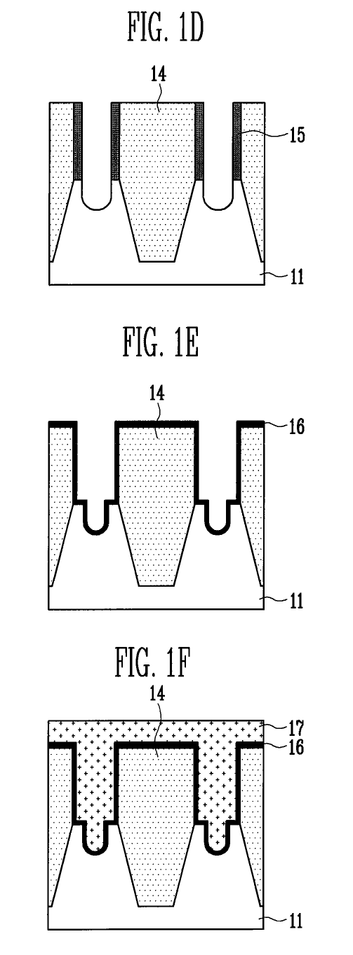

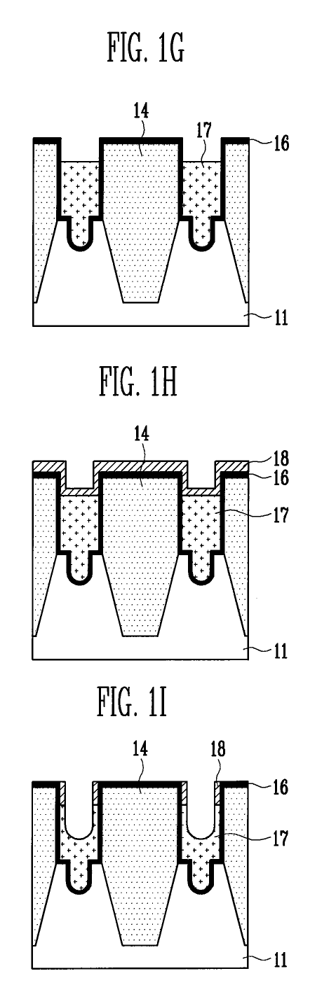

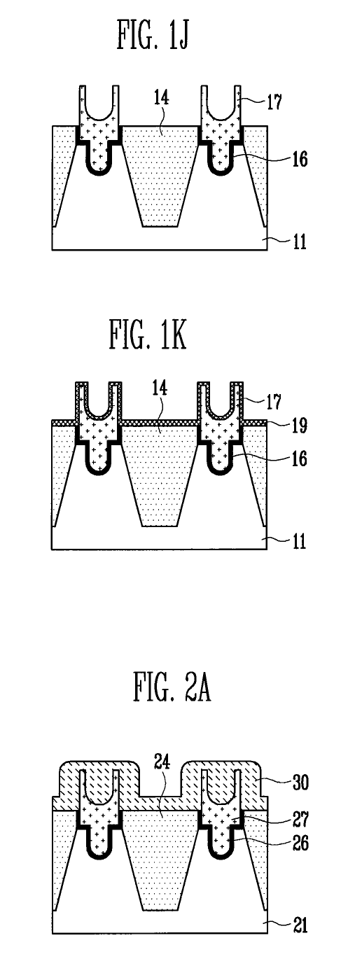

FIGS. 1A to 1K are cross-sectional views illustrating a method of manufacturing a semiconductor device according to an embodiment of the present invention.

Referring to FIG. 1A, a buffer oxide layer 12 and a hard mask 13 are formed over a semiconductor substrate 11 including an active region. The hard mask 13 can be formed from a nitride layer.

The hard mask 13, the buffer oxide layer 12 and the semiconductor substrate 11 are partially removed by performing an etch process employing a mask (not illustrated). An isolation process for forming a trench is then performed.

Referring to FIG. 1B, an insulating layer is formed on the entire surface including the trench, so that the trench is filled with the insulating layer. Chemical Mechanical Polishing (CMP) is then performed on the surface of the insulating layer to form an isolation layer 14. In this case, the hard mask 13 can be used as an etch-stop layer.

Referring to FIG. 1C, the hard mask 13 (refer to FIG. 1B) and the buffer oxide layer 12 (refer to FIG. 1B) are removed. The hard mask 13 can be removed by means of a wet etch employing a mixed solution of NH₄ and HF, or a H₃PO₄ solution.

Thereafter, a first spacer 15 is formed on the entire surface including the isolation layer 14. The first spacer 15 is formed to a thickness in which the shape of the isolation layer 14 can be maintained without completely filling the space defined by the isolation layer 14. The first spacer 15 can be formed from a nitride layer.

Referring to FIG. 1D, an etch process for removing part of the first spacer 15 is performed. The etch process can be carried out using an anisotropic etch process. In this case, the first spacer 15 remains only on the sidewalls of the isolation layer 14, and the active region of the semiconductor substrate 11 is exposed. The etch process on the first spacer 15 is performed wherein the nitride layer is etched more than silicon, so that the semiconductor substrate 11 remains substantially intact during the etch process. The etch process with respect to the first spacer 15 can be performed using a mixed gas of CₓF_{Y}, O₂ and Ar.

Part of the active region of the semiconductor substrate 11 is removed using the first spacer 15 as an etch mask, thereby forming a recess. The etch process is performed on the semiconductor substrate 11 wherein silicon is etched more than a nitride layer or an oxide layer. Thus, the width of the active region can be uniformly increased without employing an additional hard mask. The etch process can be performed on the semiconductor substrate 11 using a mixed gas of Cl₂ and HBr.

Referring to FIG. 1E, the first spacer 15 (refer to FIG. 1D) is removed. The first spacer 15 can be removed by means of a wet etch employing a mixed solution of NH₄ and HF, or a H₃PO₄ solution. A tunnel oxide layer 16 is then formed on the surface including the recess of the active region.

Referring to FIG. 1F, a polysilicon layer 17 for a floating gate is formed on the tunnel oxide layer 16.

Referring to FIG. 1G, a blanket etch process is performed under etch conditions in which the etch rate of the polysilicon layer 17 is much faster than that of the tunnel oxide layer 16, thereby etching back the polysilicon layer 17. In this case, the top surface of the polysilicon layer 17 can be lower than that of the isolation layer 14.

Referring to FIG. 1H, a second spacer 18 is formed on the surface including the polysilicon layer 17. The second spacer 18 is formed to a thickness in which the shapes of the isolation layer 14 and the tunnel oxide layer 16 can be maintained without completely filling the space defined by the isolation layer 14. The second spacer 18 can be formed from an oxide layer.

Referring to FIG. 1I, an etch process for removing part of the second spacer 18 is carried out. The etch process can include an anisotropic etch process. In this case, the second spacer 18 remains only on the sidewalls of the isolation layer 14, and the top surface of the polysilicon layer 17, in particular, the central portion of the polysilicon layer 17, is exposed.

Thereafter, part of the exposed region of the polysilicon layer 17 is removed using the second spacer 18 as an etch mask, thereby forming a recess. The etch process on the polysilicon layer 17 can be performed wherein silicon is more etched than a nitride layer or an oxide layer. Accordingly, the area of the floating gate can be uniformly increased without employing an additional hard mask. It is therefore possible to increase the area of a dielectric layer formed on the polysilicon layer 17 in a subsequent process. The etch process with respect to the polysilicon layer 17 can be performed using a mixed gas of Cl₂ and HBr.

Referring to FIG. 1J, an etch process for removing the top surface of the isolation layer 14 and the second spacer 18 is performed. The etch process can be performed so that the top surface of the isolation layer 14 is approximately 200 angstroms or higher than that of the active region. The etch process can be performed using a mixed solution of a NH₄F solution and a HF solution, or a mixed solution of a H₂SO₄ solution and a H₂O₂ solution.

Referring to FIG. 1K, a dielectric layer 19 is formed on the surface including the polysilicon layer 17. The dielectric layer 19 can have a general Oxide/Nitride/Oxide (ONO) structure. Thereafter, a control gate (not illustrated), an electrode (not illustrated) and the like may be formed on the dielectric layer 19. An etching process is then performed to form a cell. The above embodiment can be applied when forming a Single Level Cell (SLC).

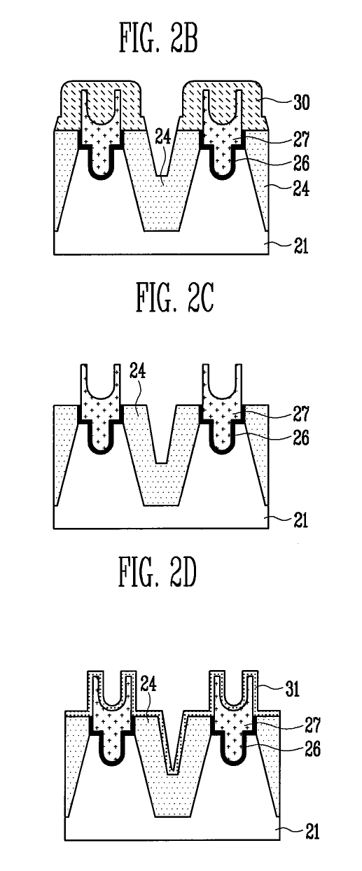

FIGS. 2A to 2D are cross-sectional views illustrating a method of manufacturing a semiconductor device according to another embodiment of the present invention.

Referring to FIG. 2A, a buffer oxide layer (not illustrated) and a hard mask (not illustrated) are formed over a semiconductor substrate 21 including an active region. The hard mask can be formed from a nitride layer.

The hard mask, the buffer oxide layer and the semiconductor substrate 21 are partially removed by an etch process employing a mask (not illustrated). An isolation process for forming a trench is then performed.

An insulating layer is formed on the surface including the trench, so that the trench is filled with the insulating layer. CMP is then performed on the surface of the insulating layer to form an isolation layer 24. In this case, the hard mask can be used as an etch-stop layer. The hard mask and the buffer oxide layer are removed. The hard mask can be removed by a wet etch employing a mixed solution of NH₄ and HF, or a H₃PO₄ solution.

Thereafter, a third spacer (not illustrated) is formed on the surface including the isolation layer 24. The third spacer can be formed to a thickness in which the shape of the isolation layer 24 can remain intact without completely filling a space defined by the isolation layer 24. The third spacer can be formed from a nitride layer.

An etch process for removing part of the third spacer is then performed. The etch process can be carried out using an anisotropic etch process. In this case, the third spacer remains on the sidewalls of the isolation layer 24, and the active region of the semiconductor substrate 21 is exposed. The etch process on the third spacer can be performed wherein a nitride layer is more etched than silicon, so that the semiconductor substrate 21 remains substantially intact during the etch process. The etch process on the third spacer can be performed using a mixed gas of CₓF_{Y}, O₂ and Ar.

The third spacer is removed by a wet etch employing a mixed solution of NH₄ and HF, or a H₃PO₄ solution. A tunnel oxide layer 26 is then formed on the surface including the recess of the active region.

Thereafter, a polysilicon layer 27 for a floating gate is formed on the tunnel oxide layer 26. A blanket etch process is then performed under etch conditions in which the etch rate of polysilicon is much faster than that of the oxide layer, thereby etching back the polysilicon layer 27. In this case, the top surface of the polysilicon layer 27 can be lower than that of the isolation layer 24.

Thereafter, a fourth spacer is formed on the entire surface including the polysilicon layer 27. The fourth spacer can be formed to a thickness in which the shapes of the isolation layer 24 and the tunnel oxide layer 26 can remain intact without completely filling the space between the isolation layers 24. The fourth spacer can be formed from an oxide layer. An etch process for removing part of the fourth spacer is then carried out. The etch process can include an anisotropic etch process. In this case, the fourth spacer remains only on the sidewalls of the isolation layer 24, and the top surface of the polysilicon layer 27, in particular, the central portion of the polysilicon layer 27, is exposed.

Thereafter, part of the exposed region of the polysilicon layer 27 is removed using the fourth spacer as an etch mask, thereby forming a recess. The etch process on the polysilicon layer 27 can be performed wherein silicon is more etched than a nitride layer or an oxide layer. Accordingly, the area of the floating gate can be uniformly increased without employing an additional hard mask. It is therefore possible to increase the area of a dielectric layer formed on the polysilicon layer 27 in a subsequent process. The etch process on the polysilicon layer 27 can be performed using a mixed gas of Cl₂ and HBr. Thereafter, an etch process for removing the top surface of the isolation layer 24 and the fourth spacer is performed. The etch process can be performed so that the top surface of the isolation layer 24 is approximately 300 angstroms or higher than that of the active region. The etch process can be performed using a mixed solution of a NH₄F solution and a HF solution, or a mixed solution of a H₂SO₄ solution and a H₂O₂ solution.

Thereafter, a fifth spacer 30 is formed on the surface including the polysilicon layer 27. The fifth spacer 30 can include a nitride layer.

Referring to FIG. 2B, an etch process for removing part of the fifth spacer 30 is performed. The etch process can include an anisotropic etch process. In this case, the fifth spacer 30 formed on the top surface of the isolation layer 24 is removed due to the shape of the polysilicon layer 27, so that the top surface of the isolation layer 24, in particular, the central portion of the isolation layer 24, can be removed.

Part of the exposed region of the isolation layer 24 is removed by an etch process using the fifth spacer 30 as an etch mask, thereby forming a recess up to the bottom of the active region. The recess can reduce an electrical interference phenomenon between the floating gates by isolating neighboring floating gates. The etch process on the isolation layer 24 can be performed wherein an oxide layer is more etched than a nitride layer.

Referring to FIG. 2C, the fifth spacer 30 (refer to FIG. 2B) is removed. The fifth spacer 30 can be removed by a wet etch process employing a mixed solution of NH₄ and HF, or a H₃PO₄ solution. Further, the etch process can be performed so that the top surface of the isolation layer 24 remains approximately 200 angstroms or higher than that of the active region.

Referring to FIG. 2D, a dielectric layer 31 is formed on the surface including the polysilicon layer 27. The dielectric layer 31 can have a general ONO structure. Thereafter, a control gate (not illustrated), an electrode (not illustrated) and the like, are formed on the dielectric layer 31. An etching process is then performed to form a cell. The above embodiment can be applied when forming a Multi Level Cell (MLC).

As described above, according to the present invention, the width of an active region can be uniformly increased without employing an additional hard mask, and the area of a floating gate can be uniformly increased. It is therefore possible to increase the area of a dielectric layer. Furthermore, a recess is formed in an isolation layer to isolate neighboring floating gates. Accordingly, an electrical interference phenomenon between the floating gates can be reduced.

Although the foregoing description has been made with reference to the specific embodiments, it is to be understood that changes and modifications of the present patent may be made by one having ordinary skill in the art without departing from the spirit and scope of the present patent and appended claims.

What is claimed is:

1. A method of manufacturing a semiconductor device, the method comprising:
forming a first spacer over a semiconductor substrate including an isolation layer defining an active region;
removing part of the first spacer to expose part of the active region;
etching the exposed active region to form a first recess;
removing the first spacer;
forming a tunnel oxide layer and a conductive layer over the surface including the recess;
forming a second spacer over the surface including the conductive layer;
removing part of the second spacer to expose part of the conductive layer;
etching the exposed conductive layer to form a second recess;
removing the second spacer; and
forming a dielectric layer and a control gate over the conductive layer.

2. The method of claim 1, wherein the first spacer is formed to a thickness in which the shape of the isolation layer remains intact without completely filling a space defined by the isolation layer.

3. The method of claim 1, wherein the first spacer is formed from a nitride layer.

4. The method of claim 3, wherein when removing part of the first spacer, an etch process is performed wherein a nitride layer is etched faster than silicon material.

5. The method of claim 4, wherein the etch process is performed using a mixed gas of CₓF_{Y}, O₂ and Ar.

6. The method of claim 1, wherein the first recess is formed by performing an etch process in which silicon material is etched faster than a nitride layer or an oxide layer.

7. The method of claim 6, wherein the etch process is performed using a mixed gas of Cl₂ and HBr.

8. The method of claim 1, wherein the first spacer is removed by a wet etch employing a mixed solution of NH₄ and HF, or a H₃PO₄ solution.

9. The method of claim 1, wherein the second spacer is formed to a thickness in which the shape of the isolation layer remains intact without completely filling a space defined by the isolation layer.

10. The method of claim 1, wherein the second spacer is formed from an oxide layer.

11. The method of claim 10, wherein the second recess is formed by performing an etch process in which silicon material is etched faster than a nitride layer or an oxide layer.

12. The method of claim 11, wherein the etch process is performed using a mixed gas of Cl₂ and HBr.

13. The method of claim 1, wherein the second spacer is removed by an etch process by which a top surface of the isolation layer is also removed.

14. The method of claim 13, wherein the etch process is performed using a mixed solution of a NH₄F solution and a HF solution, or a mixed solution of a H₂SO₄ solution and a H₂O₂ solution.

15. The method of claim 1, wherein the conductive layer includes polysilicon.

16. The method of claim 1, wherein a top surface of the conductive layer is lower in height than that of the isolation layer.

17. The method of claim 1, wherein the exposed active region is etched using the first spacer as an etch mask.

18. The method of claim 1, wherein the exposed conductive layer is etched using the second spacer as an etch mask.

19. A method of manufacturing a semiconductor device, the method comprising:
forming a first spacer over a semiconductor substrate including an isolation layer defining an active region;
removing part of the first spacer to expose part of the active region;
etching the exposed active region to form a first recess;
forming a tunnel oxide layer and a conductive layer over the surface including the recess;
forming a second spacer over the surface including the conductive layer;
removing part of the second spacer to expose part of the conductive layer;
etching the exposed conductive layer to form a second recess;
forming a third spacer over the conductive layer;
removing part of the third spacer to expose part of the isolation layer;
etching the exposed isolation layer to form a third recess; and
forming a dielectric layer and a control gate over the conductive layer.

20. The method of claim 19, wherein the third spacer is formed from a nitride layer.

21. The method of claim 20, wherein the third spacer is formed by an etch process in which an oxide layer is etched faster than a nitride layer.

22. The method of claim 19, further comprising removing the first spacer.

23. The method of claim 19, further comprising removing the second spacer.

24. The method of claim 19, further comprising removing the third spacer by a wet etch employing a mixed solution of NH₄ and HF, or a H₃PO₄ solution.

25. The method of claim 19, wherein the exposed active region is etched using the first spacer as an etch mask.

26. The method of claim 19, wherein the exposed conductive layer is etched using the second spacer as an etch mask.

27. The method of claim 19, wherein the exposed isolation layer is etched using the third spacer as an etch mask.
